(19) United States
(12) Patent Application Publication
(10) Pub. No.: US 2018/0138888 A1
(43) Pub. Date: May 17, 2018

(54) BULK ACOUSTIC WAVE RESONATOR AND METHOD OF MANUFACTURING THE SAME

(71) Applicant: SAMSUNG ELECTRO-MECHANICS CO., LTD., Suwon-si (KR)

(72) Inventors: Sang Kee YOON, Suwon-si (KR); Hyung Jae PARK, Suwon-si (KR); Nam Soo PARK, Suwon-si (KR); Jong Woon KIM, Suwon-si (KR); Moon Chul LEE, Suwon-si (KR)

(73) Assignee: SAMSUNG ELECTRO-MECHANICS CO., LTD., Suwon-si (KR)

(21) Appl. No.: 15/789,194

(22) Filed: Oct. 20, 2017

(30) Foreign Application Priority Data
Nov. 17, 2016 (KR) 10-2016-0153015
Mar. 23, 2017 (KR) 10-2017-0036661

(51) Int. Cl. H03H 9/17; H03H 3/02; H03H 9/13; H01L 41/08; H01L 41/29; H01L 41/35

(52) U.S. Cl. CPC H03H 9/17; H03H 3/02; H03H 9/13; H01L 41/0477; H01L 41/29; H01L 41/35; H01L 41/081

(57) ABSTRACT

A bulk acoustic wave resonator includes a substrate on which a substrate protective layer is disposed, a membrane layer forming a cavity together with the substrate, and a resonant portion disposed on the membrane layer. The cavity is formed by removing a sacrificial layer using a mixed gas obtained by mixing a halide-based gas and an oxygen gas, and at least one of the membrane layer and the substrate protective layer has a thickness difference of 170 Å or less, after the cavity is formed.

### CROSS-REFERENCE TO RELATED APPLICATION(S)

This application claims the benefit under 35 USC § 119(a) of Korean Patent Application No. 10-2016-0153015 filed on Nov. 17, 2016, in the Korean Intellectual Property Office, and Korean Patent Application No. 10-2017-0036661 filed on Mar. 23, 2017, in the Korean Intellectual Property Office, the entire disclosures of which are incorporated herein by reference for all purposes.

### BACKGROUND

### 1. Field

The following description relates to a bulk acoustic wave resonator and a method of manufacturing the same.

### 2. Description of Related Art

Due to recent developments in mobile communications devices, chemical and biological devices, and the like, demand for small, lightweight filters, oscillators, resonant elements, acoustic resonant mass sensors, and the like, has increased.

As a means for implementing such small, lightweight filters, oscillators, resonant elements, acoustic resonant mass sensors, and the like, a film bulk acoustic resonator (FBAR) has been developed. Such a film bulk acoustic resonator has favorable attributes, in that it may be mass-produced at a relatively low cost and may be subminiaturized.

Further, the film bulk acoustic resonator may have a high-quality factor (Q) value, as a main property of a filter, may be used in a micro-frequency band, and may particularly be implemented in bands of personal communication system (PCS) and digital cordless system (DCS).

However, in a typical film bulk acoustic resonator, a resonance part provided in the filter must remain large, which may lead to deteriorations in performance.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Examples provide a bulk acoustic wave resonator in which performance deterioration may be prevented, and a method of manufacturing the same.

In one general aspect, a bulk acoustic wave resonator includes a substrate on which a substrate protective layer is disposed, a membrane layer forming a cavity together with the substrate, and a resonant portion disposed on the membrane layer. The cavity is formed by removing a sacrificial layer using a mixed gas obtained by mixing a halide-based gas and an oxygen gas, and at least one of the membrane layer and the substrate protective layer has a thickness difference of 170 Å or less, after the cavity is formed.

Other features and aspects will be apparent from the following detailed description, the drawings, and the claims.

### BRIEF DESCRIPTION OF THE DRAWINGS

FIG. 1 is a schematic cross-sectional view illustrating an example of a bulk acoustic wave filter device.

FIG. 2 is an enlarged view of part A of FIG. 1.

FIGS. 3, 4, 5, 6, 7, 8, 9, 10, 11, and 12 are views illustrating examples of processes of a method of manufacturing the bulk acoustic wave filter device of FIG. 1.

FIG. 13 is a block diagram illustrating an example of a manufacturing facility used in a method of manufacturing the bulk acoustic wave filter device of FIG. 1.

FIG. 14 is a block diagram illustrating an example of a first modification of the manufacturing facility used in a method of manufacturing a bulk acoustic wave filter device of FIG. 1.

FIG. 15 is a block diagram illustrating an example of a second modification of the manufacturing facility used in a method of manufacturing a bulk acoustic wave filter device of FIG. 1.

Throughout the drawings and the detailed description, the same reference numerals refer to the same elements. The drawings may not be to scale, and the relative sizes, proportions, and depictions of elements in the drawings may be exaggerated for the purposes of clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

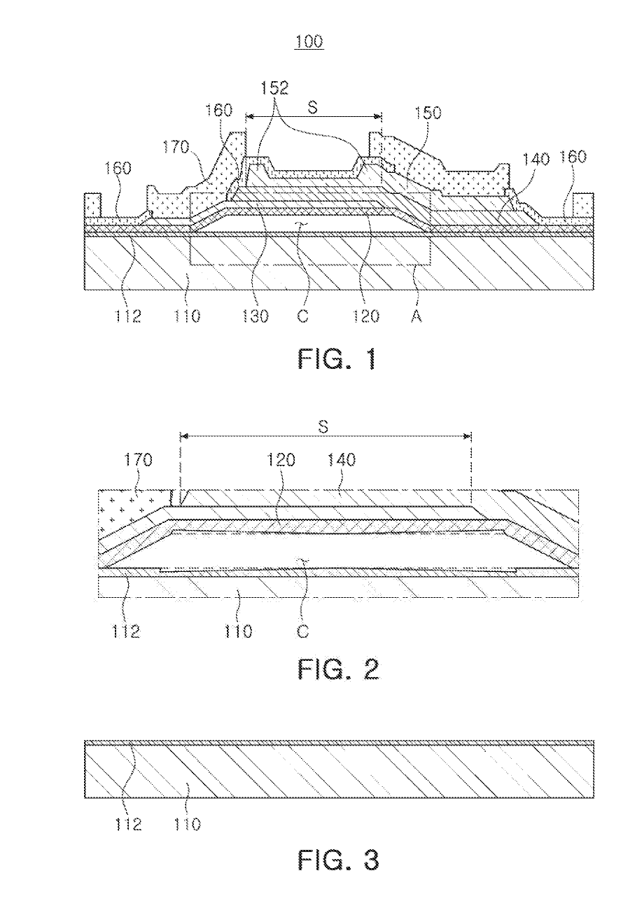

FIG. 1 is a schematic cross-sectional view of an example of a bulk acoustic wave filter device, and FIG. 2 is an enlarged view of part A of FIG. 1.

With reference to FIGS. 1 and 2, a bulk acoustic wave filter device 100 includes a substrate 110, a membrane layer 120, a lower electrode 130, a piezoelectric layer 140, an upper electrode 150, a passivation layer 160, and a metal pad 170.

The substrate 110 may be a silicon-accumulated substrate. For example, a silicon wafer is used as the substrate 110. The substrate 110 is provided with a substrate protective layer 112 formed thereon and disposed to face a cavity C.

The substrate protective layer 112 prevents the substrate 110 from being damaged when the cavity C is formed.

As an example, the substrate protective layer 112 is formed of a material including silicon nitride (SiN) or silicon oxide (SiO2).

The substrate protective layer 112 has a thickness difference of 170 Å or less in an active region S, after the cavity C is formed.

In this case, the active region S refers to a region in which all three layers of the lower electrode 130, the piezoelectric layer 140, and the upper electrode 150 are laminated vertically. The resonant portion refers to a region in which vibrations are generated, and refers to a region corresponding to the active region S.

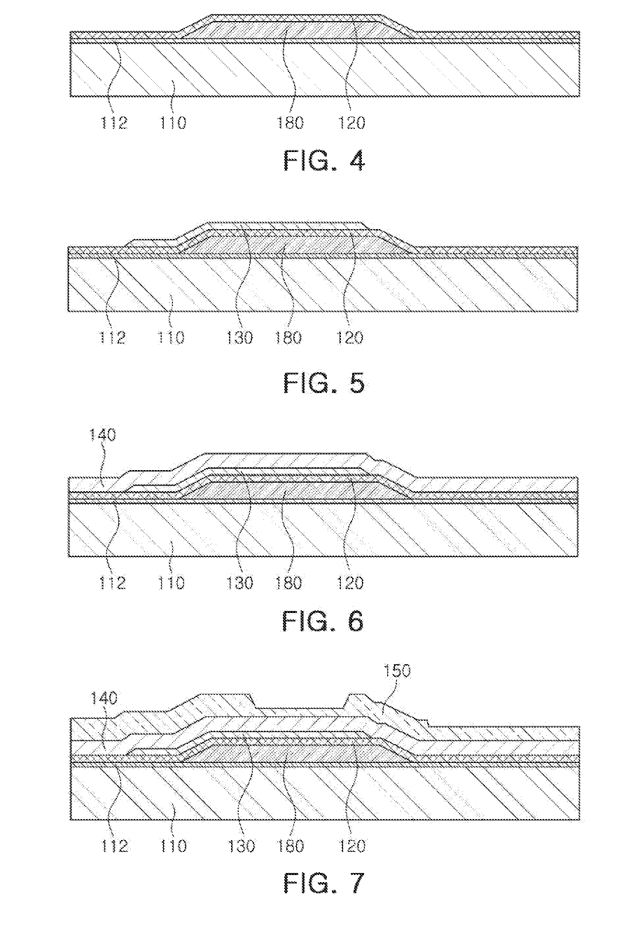

The membrane layer 120 is formed on a sacrificial layer 180 (see FIGS. 4 to 9). By removing the sacrificial layer 180, the membrane layer 120 and the substrate protective layer 112 form the cavity C. The membrane layer 120 may be formed of a material having relatively low reactivity with a mixture of an oxygen gas and a halide-based etching gas such as fluorine (F), chlorine (Cl) or the like, for removal of the sacrificial layer 180 formed of a silicon-based material.

As an example, when mixed xenon difluoride (XeF₂) and oxygen gas is used to remove the sacrificial layer 180 is used in the structure described above, damage to the membrane layer 120 and the substrate protective layer 112 causing a reduction in thickness may be decreased.

In related art, only xenon difluoride (XeF₂) is used to remove the sacrificial layer 180. Thus, in the related art, the membrane layer and the substrate protective layer may react with halide-based etching gas or reaction by-products to form an inclined surface having a slope on the membrane layer and the substrate protective layer, thereby causing a thickness deviation in a thickness direction.

However, as shown described above with reference to FIG. 1, since a mixed gas obtained by mixing oxygen gas and a halide-based etching gas such as fluorine (F), chlorine (Cl) or the like is used to remove the sacrificial layer 180, damage to the membrane layer 120 and the substrate protective layer 112 may be reduced. Thus, a reduction in thickness due to damage to the substrate protective layer 112 and the membrane layer 120 may be significantly reduced.

As an example, the membrane layer 120 is formed of a dielectric layer including one of silicon nitride (SiN), silicon oxide (SiO2), manganese oxide (MgO), zirconium oxide (ZrO2), aluminum nitride (AlN), lead zirconate titanate (PZT), gallium arsenide (GaAs), hafnium oxide (HfO2), aluminum oxide (Al2O3), titanium oxide (TiO2) and zinc oxide (ZnO), or a metal layer including one of aluminum (Al), nickel (Ni), chromium (Cr), platinum (Pt), gallium (Ga), and hafnium (Hf).

A supply amount of the oxygen gas mixed with the halide-based gas may be within a range of 2 standard cubic centimeters per min (sccm) to 100 sccm or less.

The lower electrode 130 is formed on the membrane layer 120. As an example, the lower electrode 130 is formed using a conductive material, such as molybdenum (Mo), ruthenium (Ru), tungsten (W), iridium (Ir), platinum (Pt), or the like, or alloys thereof.

The lower electrode 130 may be used as either an input electrode or an output electrode, receiving or providing an electrical signal, such as a radio frequency (RF) signal or the like.

The piezoelectric layer 140 is formed to cover at least a portion of the lower electrode 130. The piezoelectric layer 140 converts a signal input through the lower electrode 130 or the upper electrode 150 into a bulk acoustic wave. For example, the piezoelectric layer 140 converts electrical signals into bulk acoustic waves by physical vibrations.

As an example, the piezoelectric layer 140 is formed by depositing aluminum nitride, doped aluminum nitride, zinc oxide, or lead zirconate titanate.

When the piezoelectric layer 140 includes aluminum nitride (AlN), the piezoelectric layer 140 may further include a rare earth metal. As the rare earth metal, for example, at least one of scandium (Sc), erbium (Er), yttrium (Y), and lanthanum (La) is used. Further, when the piezoelectric layer 140 includes aluminum nitride (AlN), the piezoelectric layer 140 may further include a transition metal. For example, as the transition metal, at least one of zirconium (Zr), titanium (Ti), magnesium (Mg), and hafnium (Hf) may be used.

The upper electrode 150 is formed to cover the piezoelectric layer 140, and may be formed using a conductive material, such as molybdenum (Mo), ruthenium (Ru), tungsten (W), iridium (Ir), platinum (Pt) or the like, or alloys thereof, in a manner similar to the lower electrode 130.

The upper electrode 150 may be used as either an input electrode or an output electrode, receiving or providing an electrical signal, such as a radio frequency (RF) signal or the like. For example, when the lower electrode 130 is used as an input electrode, the upper electrode 150 may be used as an output electrode, and when the lower electrode 130 is used as an output electrode, the upper electrode 150 may be used as an input electrode.

A frame portion 152 is provided on the upper electrode 150. The frame portion 152 refers to a portion of the upper electrode 150 having a thickness greater than that of a remaining portion of the upper electrode 150. The frame portion 152 is provided on the upper electrode 150, such that the frame portion is disposed in a region of the active region S excluding a central portion of the active region S.

The frame portion 152 reflects lateral waves generated during resonance to an inside of the active region S, so resonance energy is confined to the active region S. In other words, the frame portion 152 is disposed at an edge of the active region S, to prevent vibrations from escaping externally from the active region S.

The passivation layer 160 is formed in a region except for portions of the lower electrode 130 and the upper electrode 150. The passivation layer 160 prevents the upper electrode 150 and the lower electrode 130 from being damaged during manufacturing processes.

Further, thickness of the passivation layer 160 may be adjusted by adjusting etching processes. Adjustment of the thickness of the passivation layer 160 may adjust a frequency. The passivation layer 160 may be formed using the same material as that of the membrane layer 120. For example, as the passivation layer 160, a dielectric layer including any one of manganese oxide (MgO), zirconium oxide (ZrO2), aluminum nitride (AlN), lead zirconate titanate (PZT), gallium arsenide (GaAs), hafnium oxide (HfO2), aluminum oxide (Al2O3), titanium oxide (TiO2) and zinc oxide (ZnO) is used.

The metal pad 170 is formed on portions of the lower electrode 130 and the upper electrode 150, on which the passivation layer 160 is not formed. As an example, the metal pad 170 may be formed of a material, such as gold (Au), a gold-tin (Au—Sn) alloy, copper (Cu), a copper-tin (Cu—Sn) alloy, and/or the like.

Although the substrate protective layer 112 and the membrane layer 120 are illustrated in the drawings as both being formed of a material including a silicon-based material, the material of the substrate protective layer 112 and the membrane layer 120 is not limited thereto. For example, only the substrate protective layer 112 may be formed of a material including a silicon-based material, or only the membrane layer 120 may be formed of a material including a silicon-based material.

For example, the substrate protective layer 112 may be formed of a material which is not etched by an etching gas, for example, xenon difluoride (XeF₂), while the membrane layer 120 may be formed of a material having fine etching via reaction thereof with etching gas. Alternatively, the membrane layer 120 may also be formed of a material which is not etched by an etching gas, for example, xenon difluoride (XeF₂), while the substrate protective layer 112 may be formed of a material having fine etching via a reaction thereof with etching gas.

As described above, a reduction in thickness due to damage to the substrate protection layer 112 and the membrane layer 120 may be significantly suppressed, and as a result, performance degradation may be prevented.

FIGS. 3 to 12 are views illustrating processes in an example of method of manufacturing a bulk acoustic wave filter device.

First, as illustrated in FIG. 3, a substrate protective layer 112 is formed on a substrate 110. As an example, the substrate protective layer 112 is formed of a material including silicon nitride (SiN) or silicon oxide (SiO₂).

Then, as illustrated in FIG. 4, a sacrificial layer 180 is formed on the substrate protective layer 112. For example, the sacrificial layer 180 is formed of a silicon-based material, and then removed by a mixture of an oxygen gas and a halide-based etching gas such as fluorine (F), chlorine (Cl), or the like.

A membrane layer 120 may be formed to cover the sacrificial layer 180.

Ultimately, the membrane layer 120 forms a cavity C by removal of the sacrificial layer 180. The membrane layer 120 may be formed of a material having relatively low reactivity with a halide-based etching gas such as fluorine (F), chlorine (Cl), or the like for removal of the sacrificial layer 180 formed of a silicon-based material.

Then, as illustrated in FIG. 5, a lower electrode 130 is formed on the membrane layer 120. A portion of the lower electrode 130 is disposed above the sacrificial layer 180, and a portion of the lower electrode 130 is formed to protrude outwardly of the sacrificial layer 180.

As an example, the lower electrode 130 is formed using a conductive material, such as molybdenum (Mo), ruthenium (Ru), tungsten (W), iridium (Ir), platinum (Pt), or the like, or alloys thereof.

Then, as illustrated in FIG. 6, a piezoelectric layer 140 is formed to cover the lower electrode 130. The piezoelectric layer 140 may be formed by depositing aluminum nitride, doped aluminum nitride, zinc oxide, or lead zirconate titanate.

Then, as illustrated in FIG. 7, an upper electrode 150 is disposed to cover the piezoelectric layer 140. The upper electrode 150 may be formed using a conductive material, such as molybdenum (Mo), ruthenium (Ru), tungsten (W), iridium (Ir), platinum (Pt), or the like, or alloys thereof.

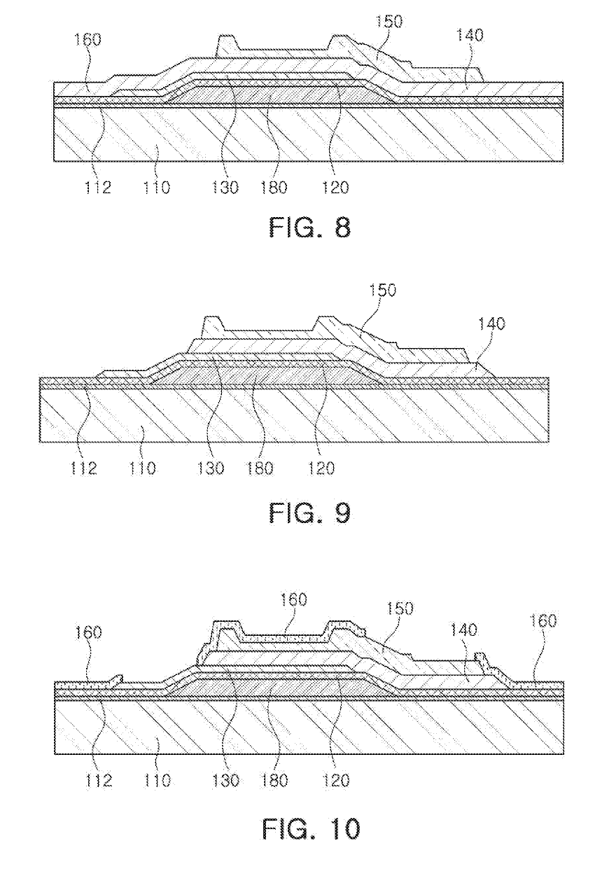

Then, as illustrated in FIG. 8, a portion of the upper electrode 150 is removed by dry etching.

Subsequently, as illustrated in FIG. 9, an edge portion of the piezoelectric layer 140 is removed by etching. Thus, a portion of the lower electrode 130 disposed below the piezoelectric layer 140 is externally exposed.

Then, as illustrated in FIG. 10, a passivation layer 160 is formed on a portion of the upper electrode 150 and an externally exposed portion of the lower electrode 130. For example, when the passivation layer 160 is formed, the passivation layer 160 is formed in such a manner that a portion of the upper electrode 150 and a portion of the lower electrode 130 are externally exposed.

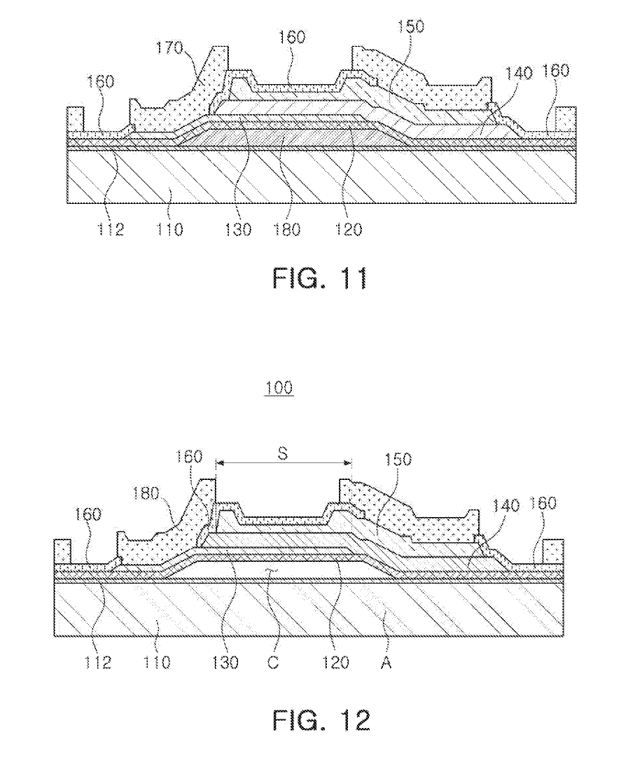

Subsequently, as illustrated in FIG. 11, a metal pad 170 is formed on the exposed portions of the lower electrode 130 and the upper electrode 150 and connected thereto. The metal pad 170 may be formed of a material, such as gold (Au), a gold-tin (Au—Sn) alloy, or the like.

Then, as illustrated in FIG. 12, the sacrificial layer 180 is removed to form the cavity C below the membrane layer 120.

The sacrificial layer 180 is removed by reaction with a mixture of an oxygen gas and a halide-based etching gas such as fluorine (F), chlorine (Cl), or the like. For example, by supplying a mixed gas such that the mixed gas obtained by mixing a halide-based etching gas and an oxygen gas contacts the sacrificial layer 180, the sacrificial layer 180 may be removed to form the cavity C.

As such, as a mixed gas obtained by mixing an oxygen gas and a halide-based etching gas such as fluorine (F), chlorine (Cl) or the like is used to remove the sacrificial layer 180, damage to the substrate protective layer 112 and the membrane layer 120 may be suppressed. Thus, a reduction in thickness due to damage to the substrate protective layer 112 and the membrane layer 120 may be significantly suppressed.

As an example, the halide-based etching gas is xenon difluoride (XeF₂).

The substrate protective layer 112 has, for example, a thickness difference of 170 Å or less in an active region S, after the cavity C is formed.

A supply amount of the oxygen gas mixed with the halide-based gas may be within a range of 2 standard cubic centimeters per min (sccm) to 100 sccm or less.

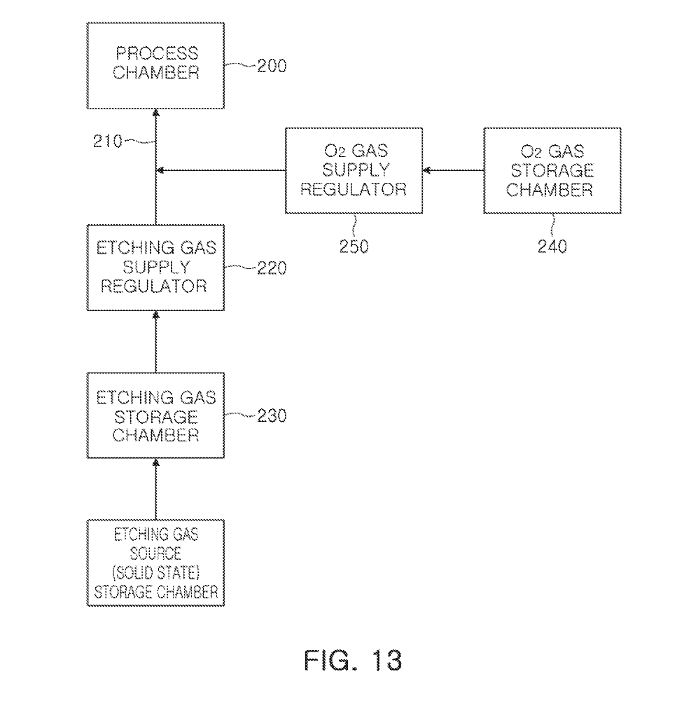

FIG. 13 is a block diagram of an example of a manufacturing facility used in a method of manufacturing a bulk acoustic wave filter device according FIG. 1.

As illustrated in FIG. 13, a process chamber 200 for removal of the sacrificial layer 180 (see FIG. 4) is provided, and a mixture of a halide-based etching gas and an oxygen gas is supplied to the process chamber 200.

The mixed gas may be supplied to the process chamber 200 through a mixed gas supply pipe 210 connected to the process chamber 200.

Etching gas, for example, xenon difluoride (XeF₂), is generated via an etching gas source stored in a solid state, is stored in an etching gas storage chamber 230, and is supplied to the mixed gas supply pipe 210 by an etching gas supply regulator 220.

The oxygen gas is stored in an oxygen (O₂) gas storage chamber 240, and is supplied to the mixed gas supply pipe 210 through an oxygen gas supply regulator 250.

Thus, a mixture of a halide-based etching gas and an oxygen gas may be supplied to the process chamber 200.

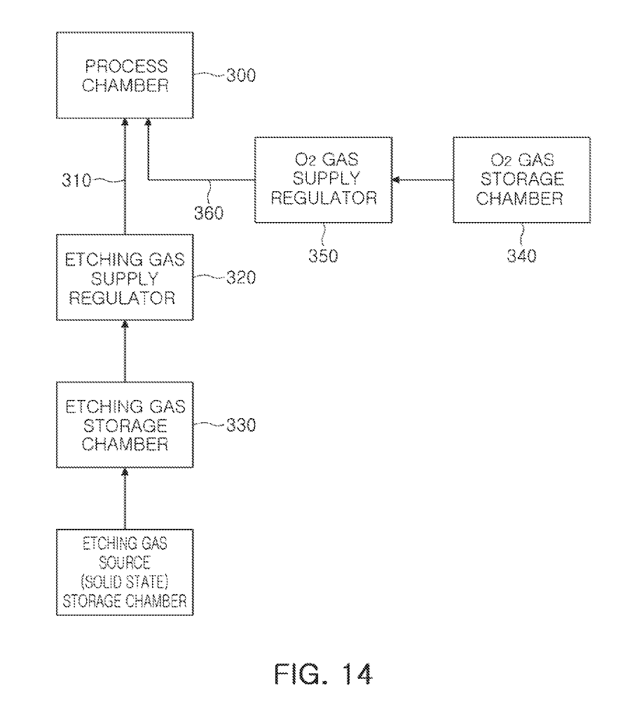

FIG. 14 is a block diagram illustrating an example of a first modification of the manufacturing facility used in a method of manufacturing a bulk acoustic wave filter device in FIG. 1.

As illustrated in FIG. 14, a process chamber 300 for removal of the sacrificial layer 180 (see FIG. 4) is provided, and a halide-based etching gas and an oxygen gas are respectively supplied to the process chamber 300.

An etching gas is supplied to the process chamber 300 via an etching gas supply pipe 310 connected to the process chamber 300, and an oxygen gas is supplied to the process chamber 300 via an oxygen gas supply pipe 360.

The etching gas, for example, xenon difluoride (XeF₂) is generated via an etching gas source stored in a solid state, is stored in an etching gas storage chamber 330, and is supplied to the etching gas supply pipe 310 by an etching gas supply regulator 320.

The oxygen gas is stored in an oxygen gas storage chamber 340, and is supplied to the oxygen gas supply pipe 360 through an oxygen gas supply regulator 350.

Thus, a mixed gas obtained by mixing a halide-based etching gas and an oxygen gas may be supplied to the process chamber 300.

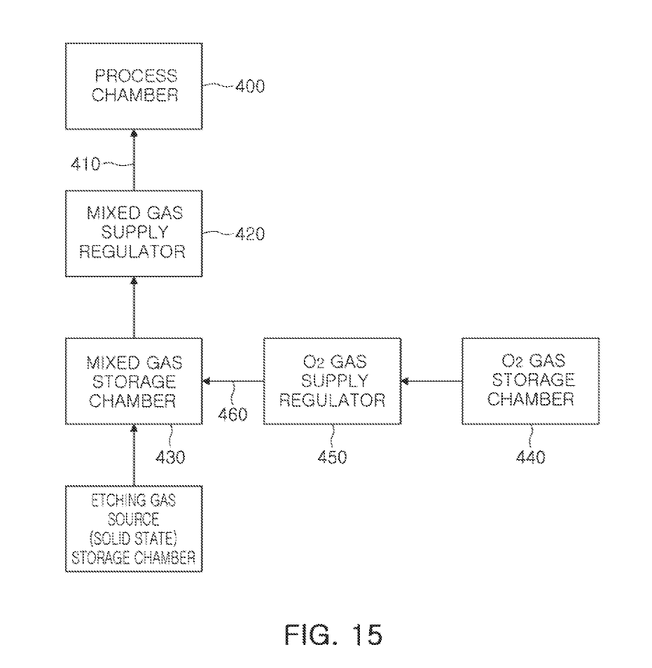

FIG. 15 is a block diagram illustrating an example of a second modification of the manufacturing facility used in a method of manufacturing a bulk acoustic wave filter device of FIG. 1.

As illustrated in FIG. 15, a process chamber 400 for removal of the sacrificial layer 180 (see FIG. 4) is provided, and a mixture of a halide-based etching gas and an oxygen gas is supplied to the process chamber 400.

The mixture of an etching gas and an oxygen gas is supplied to the process chamber 400 through a mixed gas supply pipe 410 connected to the process chamber 400.

The etching gas, for example, xenon difluoride (XeF₂), is generated through an etching gas source stored in a solid state, is stored in a mixed gas storage chamber 430, and is then supplied to the mixed gas supply pipe 410 by a mixed gas supply regulator 420.

The oxygen gas is stored in an oxygen gas storage chamber 440, and is supplied to an oxygen gas supply pipe 460 through an oxygen gas supply regulator 450. The oxygen gas supply pipe 460 is connected to the mixed gas storage chamber 430, such that oxygen gas may be supplied to the mixed gas storage chamber 430.

As such, the etching gas and the oxygen gas are mixed in the mixed gas storage chamber 430, and then, the mixed gas may be supplied to the process chamber 400 through the mixed gas supply regulator 420.

Thus, a mixed gas obtained by mixing a halide-based etching gas and an oxygen gas may be supplied to the process chamber 400.

As set forth above, according to examples, deteriorations in performance may be prevented.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for the purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic wave resonator, comprising:
a substrate protective layer disposed on a substrate;
a cavity defined by a membrane layer and the substrate; and
a resonant portion disposed on the membrane layer, wherein:
the cavity has physical characteristics defined by a sacrificial layer being removed using a mixed gas comprising a halide-based gas and an oxygen gas, and
one or both of the membrane layer and the substrate protective layer has a thickness difference of 170 Å or less, after the cavity is formed.

2. The bulk acoustic wave resonator of claim 1, wherein either one or both of the membrane layer and the substrate protective layer comprises silicon nitride or silicon oxide.

3. The bulk acoustic wave resonator of claim 1, wherein the resonant portion comprises:
a lower electrode disposed on the membrane layer;
a piezoelectric layer covering at least a portion of the lower electrode; and
an upper electrode disposed on the piezoelectric layer.

4. The bulk acoustic wave resonator of claim 3, further comprising:
a passivation layer disposed in a region in which portions of the upper electrode and the lower electrode are not disposed; and
a metal pad disposed on the portions of the upper electrode and the lower electrode, on which the passivation layer is not disposed.

5. The bulk acoustic wave resonator of claim 3, further comprising:
a frame portion disposed on the upper electrode at an edge of an active region.

6. A method of forming a bulk acoustic wave resonator, the method comprising:
forming a sacrificial layer on a substrate protective layer;
forming a membrane layer on the substrate protective layer and covering the sacrificial layer;
forming a resonant portion on the membrane layer;
forming a passivation layer to cover the resonant portion;
patterning the passivation layer to expose a portion of the resonant portion;
forming a metal pad connected to the resonant portion; and
removing the sacrificial layer, using a mixed gas comprising a halide-based gas and an oxygen gas, to form a cavity.

7. The method of claim 6, wherein one or both of the membrane layer and the substrate protective layer comprises silicon nitride or silicon oxide.

8. The method of claim 6, wherein one or both of the membrane layer and the substrate protective layer has a thickness difference of 170 Å or less, after the sacrificial layer is removed.

9. The method of claim 6, wherein the forming a resonant portion on the membrane layer comprises:
forming a lower electrode on the membrane layer such that a portion of the lower electrode is disposed on the sacrificial layer;
forming a piezoelectric layer covering a portion of the lower electrode; and
forming an upper electrode on the piezoelectric layer.

10. The method of claim 6, wherein an amount of the oxygen gas mixed with the halide-based gas is within a range of 2 standard cubic centimeters per min (sccm) to 100 sccm.

11. The method of claim 10, wherein the halide-based gas is xenon difluoride (XeF₂).

12. The method of claim 6, wherein the mixed gas is provided to the sacrificial layer through a mixed gas supply pipe.

13. The method of claim 12, wherein the halide-based gas is stored in an etching gas storage chamber, the oxygen gas is stored in an oxygen gas storage chamber, and the halide-based gas and the oxygen gas are mixed in the mixed gas supply pipe.

14. The method of claim 6, wherein the mixed gas is obtained by mixing the halide-based gas and the oxygen gas in a mixed gas storage chamber.

15. The method of claim 14, wherein the mixed gas is provided to the sacrificial layer through a mixed gas supply pipe.

16. The method of claim 6, wherein the halide-based gas is provided to a process chamber through an etching gas supply pipe, and the oxygen gas is provided to the process chamber through an oxygen gas supply pipe.
